(19) United States
(12) Patent Application Publication
(10) Pub. No.: US 2023/0272192 A1
(43) Pub. Date: Aug. 31, 2023

(54) COVER TAPE AND ELECTRONIC COMPONENT PACKAGE

(71) Applicant: Denka Company Limited, Chuo-ku, Tokyo (JP)

(72) Inventors: Kota SAWAGUCHI, Chuo-ku, Tokyo (JP); Keisuke NABA, Chuo-ku, Tokyo (JP); Gosuke NAKAJIMA, Chuo-ku, Tokyo (JP)

(73) Assignee: Denka Company Limited, Chuo-ku, Tokyo (JP)

(21) Appl. No.: 18/006,898

(22) PCT Filed: Aug. 18, 2021
(86) PCT No.: PCT/JP2021/030216

§ 371 Date: Jan. 26, 2023

(30) Foreign Application Priority Data
Aug. 24, 2020 (JP) 2020-140976
Dec. 22, 2020 (JP) 2020-212246
Jul. 26, 2021 (JP) 2021-121394

(51) Int. Cl. C08L 9/06; B32B 27/30; B32B 27/32

(52) U.S. Cl. CPC C08L 9/06; B32B 27/302; B32B 27/32; B32B 27/308; C08L 2205/025; C08L 2205/035; B32B 27/36

(57) ABSTRACT

This cover tape has at least a base layer and a heat seal layer, wherein the heat seal layer has a loss tangent tan δ of less than 1 in a temperature range of 150° C. or less in a dynamic viscoelastic measurement at a measurement frequency of 1 Hz.

### TECHNICAL FIELD

The present invention relates to a cover tape and an electronic component package.

### BACKGROUND ART

Along with the miniaturization of electronic devices, the electronic components used are becoming smaller and having a higher performance. In the process of assembling electronic devices, components are automatically mounted on printed circuit boards. For transporting such electronic components for surface mounting, an electronic component package in which electronic components are accommodated in a carrier tape in which pockets are continuously thermoformed to match shapes of the electronic components is used to continuously supply the electronic components.

The electronic component package is manufactured by accommodating the electronic components in the pockets of the carrier tape, then stacking a cover tape having a heat seal layer as a cover material on an upper surface of the carrier tape and continuously heat sealing both ends of the cover tape in a longitudinal direction with a heated seal bar (for example, refer to Patent Literature 1).

When the electronic component package is used, the cover tape is peeled off from the carrier tape, and the electronic components are automatically taken out and surface-mounted on an electronic circuit board.

### CITATION LIST

### Patent Literature

[Patent Literature 1] Japanese Unexamined Patent Publication No. 2010-173673

### SUMMARY OF INVENTION

### Technical Problem

In recent years, the electronic components have become significantly smaller, thinner, and lighter, and when the cover tape is peeled off from the carrier tape in a process in which electronic components are mounted on an electronic circuit board, and a difference between the maximum value and the minimum value of the peel strength (hereinafter referred to as a “peel strength range”) becomes too large, there is a problem that the carrier tape vibrates violently, and the electronic components are caused to pop out, which makes mounting defects more likely to occur.

Therefore, the present inventors focused on a heat seal layer of the cover tape and studied a design of the heat seal layer to reduce the peel strength range.

The present invention has been made in view of the above circumstances, and an object thereof is to provide a cover tape capable of a reduction in a peel strength range and an electronic component package using the same.

### Solution to Problem

In order to solve the above problems, one aspect of the present invention provides a cover tape including at least a base layer, and a heat seal layer, wherein the heat seal layer has a loss tangent tan δ of less than 1 in a temperature range of 150° C. or less in a dynamic viscoelastic measurement at a measurement frequency of 1 Hz.

The above-described cover tape can be heat-sealed to the carrier tape as a cover material and can reduce a peel strength range when the cover tape is peeled off after heat-sealing. Thus, in the manufacture of electronic equipment, when the cover tape is peeled off from the electronic component package, it is possible to prevent the electronic component from popping out and to prevent mounting defects on an electronic circuit board.

The heat seal layer may contain one or more resins selected from a group consisting of a polystyrene-based resin, a polyethylene-based resin, and an acrylic-based resin, from the viewpoint of ensuring sealing strength.

The heat seal layer may have a ratio [G′(30)/G′(150)] of storage elastic modulus G′(30) at 30° C. to storage elastic modulus G′(150) at 150° C. of 800 or less in the dynamic viscoelastic measurement at the measurement frequency of 1 Hz.

The heat seal layer may have a storage elastic modulus G′(30) at 30° C. of 1.0×10⁶ Pa or more and less than 1.0×10⁸ Pa in the dynamic viscoelastic measurement at a measurement frequency of 1 Hz, from the viewpoint of blocking resistance and reduction of peel strength range.

Another aspect of the present invention provides an electronic component package including a carrier tape having an accommodating portion, electronic components accommodated in the accommodating portion of the carrier tape, and the cover tape heat-sealed to the carrier tape as a cover material.

The above-described electronic component package may have a small peel strength range when the cover tape is peeled off. Thus, in the manufacture of electronic equipment, it is possible to greatly reduce a mounting defect rate of electronic components.

### Advantageous Effects of Invention

According to the present invention, it is possible to provide a cover tape capable of reducing a peel strength range and an electronic component package using the same.

### BRIEF DESCRIPTION OF DRAWINGS

FIG. 1 is a schematic cross-sectional view showing an embodiment of a cover tape.

FIG. 2 is a partially cutaway perspective view showing an embodiment of an electronic component package.

FIG. 3 is a diagram describing a peel strength range

### DESCRIPTION OF EMBODIMENTS

Hereinafter, exemplary embodiments of the present invention are described in detail.

[Cover Tape]

A cover tape of the present embodiment includes at least a base layer and a heat seal layer.

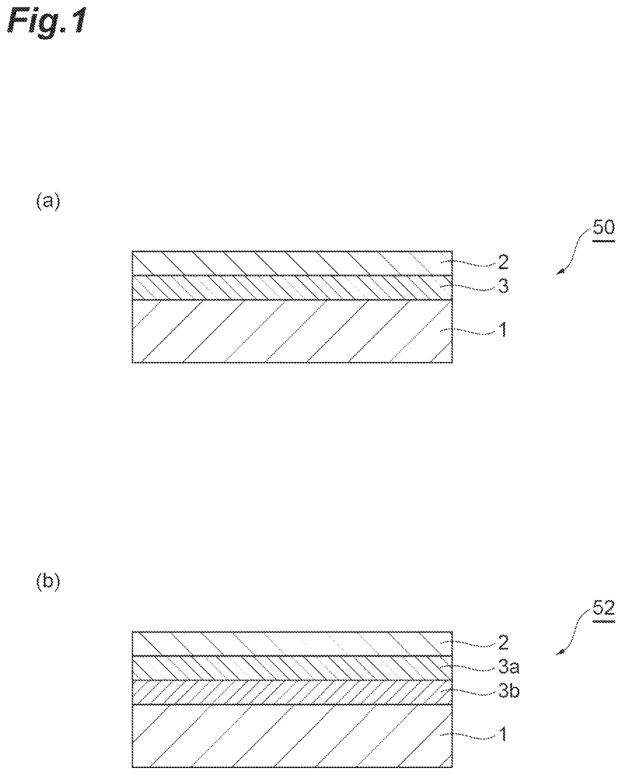

FIG. 1 is a schematic cross-sectional view showing an embodiment of a cover tape. The cover tape 50 shown in FIG. 1(a) includes a base layer 1, a heat seal layer 2 provided on one side of the base layer 1, and an intermediate layer 3 provided between the base layer 1 and the heat seal layer 2. Further, a cover tape 52 shown in FIG. 1(b) includes two intermediate layers 3a and 3b provided between the base layer 1 and the heat seal layer 2. The cover tape of the present embodiment may have a two-layer structure without the intermediate layer, and may have a structure in which a layer such as an antistatic layer is further provided on the side of the base layer 1 opposite to the heat seal layer 2, for example. In addition, the cover tape of the present embodiment may have a structure in which a layer such as an antistatic layer is further provided on the side of the heat seal layer 2 opposite to the base layer 1 as long as heat sealing properties of the heat seal layer are not impaired.

(Base Layer)

The base layer may be a film formed from a resin composition containing one or more thermoplastic resins selected from a polyester resin such as polyethylene terephthalate and polyethylene naphthalate, a polyethylene-based resin, a polyolefin-based resin other than the polyethylene-based resin, such as polypropylene, a polyamide resin such as nylon, a polystyrene resin, and a polycarbonate resin. The films are preferably biaxially stretched films from the viewpoint of mechanical strength, and more preferably biaxially stretched polyethylene terephthalate films from the viewpoint of transparency and toughness.

Examples of the polystyrene-based resin include polymers having a styrene unit in a molecular chain at a molar ratio of ½ or more, such as polystyrene, high impact polystyrene (HIPS), styrene-butadiene copolymers or hydrogenated products thereof, styrene-isoprene copolymers or hydrogenated products thereof, graft copolymers of styrene and ethylene, styrene-butene-butadiene copolymers, and copolymers of methacrylic acid and styrene, and the like. The polymers may be used singly or in combination of two or more (as a mixture).

Examples of the polyethylene-based resin include those having an ethylene unit in the molecular chain at a molar ratio of ½ or more, such as low-density polyethylene, linear low-density polyethylene, ultra-low-density polyethylene, ethylene-α-olefin, ethylene-vinyl acetate copolymer, ethylene-(meth)acrylic acid copolymer, ethylene-methyl (meth)acrylate copolymer, ethylene-ethyl (meth)acrylate copolymer, and ethylene-propylene rubber. They can be used singly or in combination of two or more (as a mixture).

Various additives such as antioxidants and lubricants that are commonly used may be added to the base layer from the viewpoint of obtaining extrusion stability when a film is formed.

The base layer may be a single layer or may have a multilayer structure.

A thickness of the base layer may be 5 to 100 μm, 10 to 80 μm, or 12 to 30 μm from the viewpoint of mechanical strength and heat transfer during heat sealing.

(Intermediate Layer)

The intermediate layer may be provided for the purpose of strengthening adhesive strength between the base layer and the heat seal layer and may include a thermoplastic resin. Examples of the thermoplastic resin include:
(i) a polyethylene resin such as low-density polyethylene, linear low-density polyethylene, and ultra-low-density polyethylene,
(ii) ethylene-1-butene, a copolymer of ethylene and unsaturated carboxylic acid, an ethylene-(meth)acrylic acid ester copolymer, an ethylene-vinyl acetate copolymer, and also a terpolymer with an acid anhydride, and a mixture thereof,
(iii) a styrene-ethylene graft copolymer, a styrene-propylene graft copolymer, a block copolymer of styrene-ethylene-butadiene, and a mixture thereof, and the like.

The thermoplastic resin is preferably a polyethylene-based resin, more preferably a low-density polyethylene resin or a linear low-density polyethylene resin, in view of the above purpose and easy layer formation.

Also, the intermediate layer may have a structure of two or more layers. In this case, due to production of a coextruded film of the heat seal layer and the intermediate layer, extrusion stability of the heat seal layer can be enhanced, while the adhesion between the coextruded film and the base layer can be improved by another intermediate layer. The intermediate layer having a structure of two or more layers may be, for example, a first intermediate layer in which the side in contact with the heat seal layer includes one or more of the resins shown in (i), (ii) and (iii) above, and may be a second intermediate layer in which the side in contact with the base layer includes one or more of the resins shown in (i) and (ii) above.

From the viewpoint of obtaining the extrusion stability during film formation, the intermediate layer may contain various additives such as antioxidants and lubricants that are commonly used.

A thickness of the intermediate layer may be 3 to 70 μm, 5 to 60 μm, or 10 to 50 μm, from the viewpoint of securing adhesive strength between the base layer and the heat seal layer and peel strength of the cover tape.

The cover tape of the present embodiment may have two or more of base layers and/or intermediate layers. In such a cover tape, for example, the base layer and the intermediate layer may have a three-layer structure of a base layer, an intermediate layer and a base layer, or may have a four-layer structure of an intermediate layer, a base layer, an intermediate layer, and a base layer.

When the cover tape of the present embodiment has two or more base layers and/or intermediate layers, a known adhesive can be used to strengthen the adhesion between the layers. Examples of the adhesive include an isocyanate adhesive and an ethyleneimine adhesive. An adhesive layer preferably has a thickness of 5 μm or less from the viewpoint of preventing large variations in the peel strength of the cover tape.

(Heat Seal Layer)

The heat seal layer can be formed from a resin composition containing resins such as a polystyrene-based resin, a polyethylene-based resin and an acrylic-based resin.

From the viewpoint of a reduction in the peel strength range, the heat seal layer can be provided so that a loss tangent tan δ is less than 1 in a temperature range of 150° C. or less in dynamic viscoelastic measurement at a measurement frequency of 1 Hz. Further, the heat seal layer may have a peak temperature of the loss tangent tan δ of 150° C. or less in the dynamic viscoelastic measurement at a measurement frequency of 1 Hz.

The loss tangent tan δ in the dynamic viscoelastic measurement of the heat seal layer may be obtained as follows.
(i) A resin composition constituting the heat seal layer is molded into a sheet having a thickness of about 1 to 2 mm to prepare a measurement sample.
(ii) The measurement sample is subjected to dynamic viscoelastic measurement using a rheometer under the following conditions to obtain the loss tangent tan δ.

### [Measurement Condition]

Measuring device: Rheometer DHR-2 (manufactured by TA Instruments Co., Ltd.)
Measurement mode: shear mode
Measuring jig: Parallel plate of φ8 mm
Frequency: 1 Hz
Distortion: 0.05%
Heating rate: 5° C./min
Measurement temperature: 25 to 200° C.

The inventors speculate as follows about the reason why the peel strength range can be reduced when the heat seal layer satisfies the above-described condition of the loss tangent tan δ.

First, it was found that when a cover tape with a large peel strength range is heat-sealed with a seal iron set at normal temperature conditions (for example, about 140° C.), an adhesive region tends to expand beyond a width of the seal iron. In such an adhesive region, an adhesive strength of a portion protruding from a portion pressed by the seal iron tends to vary, and this is considered to be the cause of the large peel strength range. On the other hand, the loss tangent tan δ is defined as G″/G′ by a storage elastic modulus G′ and a loss elastic modulus G″ obtained by the dynamic viscoelastic measurement. When the tan δ defined by G″/G′ is less than 1 in a temperature range of 150° C. or less, it means that the elasticity is superior in property to the viscosity, and the adhesion region during heat sealing is unlikely to spread. It is considered that, when the cover tape has the heat seal layer that exhibits such effects, an area of the protruding portion can be reduced when heat sealing is performed by the seal iron, and thus the peel strength range is reduced.

In the heat seal layer, in the dynamic viscoelastic measurement at a measurement frequency of 1 Hz, a ratio [G′(30)/G′(150)] of the storage elastic modulus G′(30) at 30° C. to the storage elastic modulus G′(150) at 150° C. may be 800 or less and may be 100 to 600 from the viewpoint of the reduction in the peel strength range.

In the heat seal layer, in the dynamic viscoelastic measurement at a measurement frequency of 1 Hz, the storage modulus G′(30) at 30° C. may be 1.0×10⁶ Pa or more and less than 1.0×10⁸ Pa, may be 5.0×10⁶ Pa or more and less than 1.0×10⁸ Pa, and may be 5.0×10⁶ Pa or more and 5.0×10⁷ Pa or less from the viewpoint of blocking resistance and a reduction in the peel strength range.

From the viewpoint of ensuring sealing strength, the heat seal layer can contain one or more resins selected from the group consisting of a polystyrene-based resin (hereinafter, it may be referred to as component (A)), a polyethylene-based resin (hereinafter, it may be referred to as component (B)), and an acrylic-based resin (hereinafter, it may be referred to as component (C)). In addition, the cover tape having such a heat seal layer can easily ensure sealing performance in response to carrier tapes made of various materials such as a polystyrene carrier tape and a polycarbonate carrier tape.

The heat seal layer may contain, as the component (A), a copolymer of a styrene-based hydrocarbon and a conjugated diene-based hydrocarbon, and a high impact polystyrene, or may contain a mixture thereof.

The styrene-based hydrocarbon may include styrene, α-methylstyrene, and various alkyl-substituted styrenes. The conjugated diene-based hydrocarbons include butadiene and isoprene.

The component (A) may contain a block copolymer (A-1) (hereinafter, it may be referred to as a component (A-1)) of 10% by mass or more and less than 50% by mass of a styrene-based hydrocarbon and more than 50% by mass and 90% by mass or less of a conjugated diene-based hydrocarbon, and a block copolymer (A-2) (hereinafter, it may be referred to as a component (A-2)) of 50% by mass or more and 95% by mass or less of a styrene-based hydrocarbon and 5% by mass or more and 50% by mass or less of a conjugated diene-based hydrocarbon.

Examples of the component (A-1) include a styrene-butadiene copolymer, a styrene-butylene-butylene-styrene copolymer, a styrene-ethylene-butylene-styrene copolymer, a styrene-ethylene-propylene-styrene copolymer, and a styrene-isoprene-styrene copolymer. The component (A-1) can be used singly or in combination of two or more.

A mass ratio between the styrene-based hydrocarbon and the conjugated diene-based hydrocarbon in the component (A-1) may be 10/90 to 45/55, may be 30/70 to 45/55, or may be 35/75 to 45/55 from the viewpoint of easy adjustment of the peel strength and film formation properties.

A content of the component (A-1) may be 20 to 65% by mass, may be 35 to 60% by mass, may be 40 to 55% by mass, or may be 40 to 50% by mass based on a total amount of the heat seal layer from the viewpoint of a reduction in the peel strength range.

Examples of the component (A-2) may include a styrene-butadiene copolymer, a styrene-butylene-butylene-styrene copolymer, a styrene-ethylene-butylene-styrene copolymer, a styrene-ethylene-propylene-styrene copolymer, and a styrene-isoprene-styrene copolymer. The component (A-2) can be used singly or in combination of two or more.

A mass ratio of the styrene-based hydrocarbon and the conjugated diene-based hydrocarbon in the component (A-2) may be 50/50 to 95/5, may be 70/30 to 90/10, or may be 80/20 to 85/15.

A mass ratio of the component (A-2) to the component (A-1) may be 0.30 to 2.0, may be 0.30 to 1.0, may be 0.50 to 0.90, and may be 0.65 to 0.85 from the viewpoint of the reduction in the peel strength range.

A total content of the component (A-1) and the component (A-2) in the heat seal layer may be 50 to 100% by mass, may be 50 to 95% by mass, may be 50 to 90% by mass, may be 60 to 100% by mass, may be 60 to 95% by mass, may be 60 to 90% by mass, or may be 70 to 90% by mass based on the total amount of the heat seal layer from the viewpoint of the film formation properties and the blocking resistance of the film.

When the heat seal layer contains the components (A-1) and (A-2), and a high impact polystyrene (hereinafter, it may be referred to as component (A-3)), proportional contents thereof may be 30 to 60 parts by mass for the component (A-1), 20 to 60 parts by mass for the component (A-2), and 1 to 20 parts by mass for the component (A-3), and may be 35 to 60 parts by mass for the component (A-1), 20 to 40 parts by mass for the component (A-2), and 5 to 15 parts by mass for the component (A-3) with respect to a total of 100 parts by mass of the components (A-1), (A-2) and (A-3).

A content of component (A) in the heat seal layer may be 50 to 100% by mass, may be 50 to 95% by mass, may be 60 to 100% by mass, may be 60 to 95% by mass, and may be 70 to 95% by mass based on the total amount of the heat seal layer.

The heat seal layer may contain a polystyrene resin other than the component (A). Examples of such a polystyrene resin may include a high impact polystyrene, a general-purpose polystyrene, an acrylonitrile-butadiene-styrene copolymer, and a styrene-ethylene-propylene-styrene copolymer.

A content of the polystyrene-based resin other than the component (A) may be more than 0% by mass and 25% by mass or less, may be 5 to 20% by mass, or may be 5 to 10% by mass based on the total amount of the heat seal layer from the viewpoint of the blocking resistance.

The component (B) includes those exemplified in the description of the base layer. However, a copolymer containing (meth)acrylic acid or alkyl esters thereof as a copolymerization component such as an ethylene-(meth) acrylic acid copolymer, an ethylene-methyl (meth)acrylate copolymer, and an ethylene-ethyl (meth)acrylate copolymer is included in the component (C).

The component (B) can be used singly or in combination of two or more (as a mixture).

A content of the component (B) in the heat seal layer may be 0 to 20% by mass, may be 0 to 10% by mass, and may be 0 to 5% by mass based on the total amount of the heat seal layer, from the viewpoint of the reduction in the peel strength range.

The component (C) includes an ethylene-(meth)acrylic acid copolymer.

Examples of the ethylene-(meth)acrylic acid copolymer may include an ethylene-acrylic acid copolymer (EAA), an ethylene-methacrylic acid copolymer (EMAA), an ethylene-methyl methacrylate copolymer (EMMA), an ethylene-ethyl acrylate copolymer (EEA), an ethylene-methyl acrylate copolymer (EMA), and an ethylene-glycidyl methacrylate-methyl acrylate copolymer (EGMA-MA),

The heat seal layer may contain an ethylene-methyl (meth)acrylate copolymer (C-1) (hereinafter, it may be referred to as a component (C-1)) as the component (C) from the viewpoint of ensuring sealing strength at a low temperature. As the (C-1) component, the above-described EMMA, EMA and EGMA-MA can be used.

A content of the component (C) in the heat seal layer may be 0 to 30% by mass, may be 0 to 20% by mass, and may be 0 to 10% by mass based on the total amount of the heat seal layer, from the viewpoint of the reduction in the peel strength range.

When the heat seal layer contains one or more selected from a group consisting of the component (B) and the component (C), a total content of the components (B) and (C) may be more than 0% by mass and 30% by mass or less, may be more than 0% by mass and 20% by mass or less, and may be 5 to 15% by mass based on the total amount of the heat seal layer, from the viewpoint of the reduction in the peel strength range.

A total content of the components (A), (B) and (C) in the heat seal layer may be 70 to 100% by mass, and may be 90 to 100% by mass based on the total amount of the heat seal layer, from the viewpoint of the reduction in the peel strength range.

The heat seal layer may contain various additives such as antioxidants and lubricants that are commonly used, from the viewpoint of obtaining extrusion stability during film formation.

A thickness of the heat seal layer may be 2 to 50 μm, may be 2 to 40 μm, or may be 3 to 30 μm from the viewpoint of ensuring sealing strength.

Each of the layers described above can be formed into a film by, for example, a method such as an inflation method, a T-die method, a casting method, or a calendering method. In this case, each of the components constituting each of the layers may be incorporated using a mixer such as a Henschel mixer, a tumbler mixer, or a Mazelar, and may be directly formed into a film by an extruder, or the blend may be kneaded and extruded by a single-screw or twin-screw extruder to obtain pellets, and then the pellets may be further extruded by an extruder to form a film.

The heat seal layer may be formed by a method of forming a film by extrusion molding such as inflation molding or T-die extrusion, a method of dissolving the above-described component (A), component (B) and/or component (C), and other components in a solvent and coating the film of the base layer, a method of coating as a water-based emulsion, or the like.

When a film for the heat seal layer is formed by extrusion molding, preferably, the film is co-extruded with the intermediate layer in order to improve the extrusion stability. For example, a two-layer film in which the intermediate layer and the heat seal layer are laminated can be obtained by melt-kneading a resin that forms the intermediate layer and a resin that forms the heat seal layer using separate single-screw or twin-screw extruders, laminating and integrating the two resins via a feed block or a multi-manifold die and then extruding from a T-die.

Moreover, the film for the heat seal layer obtained by extrusion molding may be laminated on the base layer by a general method such as dry laminating or extrusion laminating to form the cover tape.

An overall thickness of the cover tape may be 30 to 100 μm, may be 35 to 80 μm, and may be 40-70 μm. Within such a range, it becomes easy to ensure the strength and sealing properties of the tape.

The cover tape of the present embodiment is suitable for packaging electronic components. Examples of the electronic components include ICs, LEDs (light emitting diodes), resistors, liquid crystals, capacitors, transistors, piezoelectric element resistors, filters, crystal oscillators, crystal oscillators, diodes, connectors, switches, volumes, relays, inductors, and the like. The electronic components may be intermediate products using the components described above, or may be final products.

In the above applications, it is preferable to impart antistatic performance to the base layer and the heat seal layer in order to prevent dust attachment and to dissipate a charge of the cover tape itself. The antistatic performance can be imparted using a surfactant type, conductive metal oxide fine particles, or electron conductive polymer as a commonly used antistatic agent. Although the antistatic agent can be kneaded into the resin according to the performance to be expressed, both surface layers of the cover tape can be coated with the antistatic agent by a gravure coater or the like from the viewpoint of efficiently exhibiting effects.

The cover tape for packaging electronic components can be heat-sealed to a carrier tape, for example.

The carrier tape may have pockets for storing electronic components by a method such as air pressure molding or vacuum molding. As a material for the carrier tape, a material that can be easily formed into a sheet such as polyvinyl chloride (PVC), polystyrene (PS), polyester (A-PET, PEN, PET-G, PCTA), polypropylene (PP), polycarbonate (PC), polyacrylonitrile (PAN), acrylonitrile-butadiene-styrene copolymer (ABS) can be used. The resins can be used singly or in combination. The carrier tape may be a laminate configured of multiple layers.

The cover tape of the present embodiment can be used in combination with a carrier tape such as a carrier tape made of polystyrene or a carrier tape made of polycarbonate.

<Electronic Component Package>

An electronic component package of the present embodiment includes a carrier tape having an accommodating portion capable of accommodating electronic components, electronic components accommodated in the accommodating portion of the carrier tape, and a cover tape of the present embodiment heat-sealed to the carrier tape as a cover material.

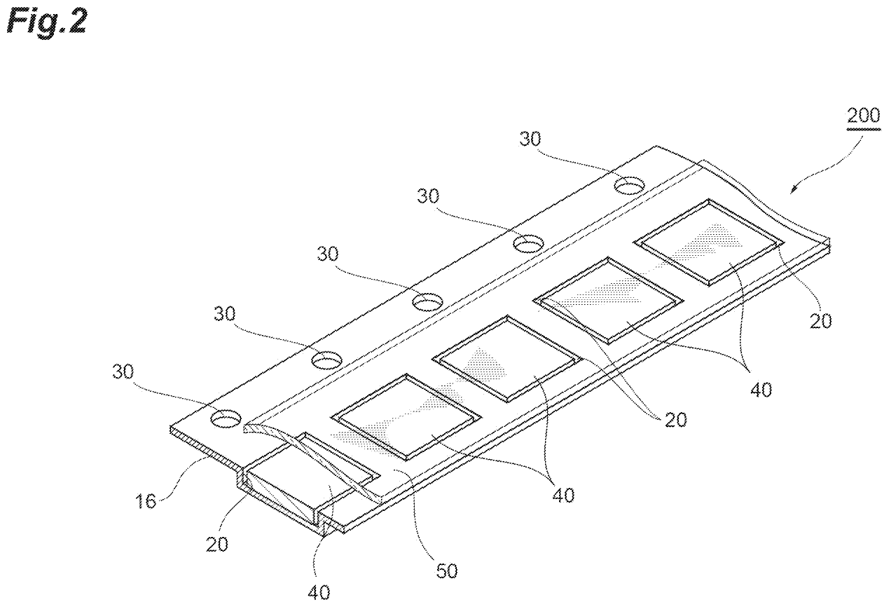

FIG. 2 is a partially cutaway perspective view showing one embodiment of the electronic component package. The electronic component package 200 shown in FIG. 2 includes an embossed carrier tape 16 having an accommodating portion 20, electronic components 40 accommodated in the accommodating portion 20, and a cover film 50 heat-sealed to the embossed carrier tape 16. Transport holes 30 that can be used for transporting various electronic components such as ICs in a sealing process are provided in the embossed carrier tape 16. Further, a hole (not shown) for electronic component inspection is provided in a bottom portion of the accommodating portion 20.

The electronic components and the carrier tape include those described above.

In the electronic component package of the present embodiment, a carrier tape wound into a reel shape can be used for storing and transporting the electronic components.

The electronic component package of the present embodiment can be manufactured by a method including a step of heat sealing the cover tape of the present embodiment to the carrier tape in which the electronic components are accommodated in the accommodating portion. Since the cover tape of the present embodiment has sufficient anti-blocking properties, even when the cover tape is wound, blocking is unlikely to occur, and it is possible to curb poor unwinding from the wound body and to efficiently perform the heat sealing process.

A member called a seal iron capable of applying a predetermined amount of heat and a predetermined pressure to the heat seal layer can be used in heat sealing of the cover tape. The cover tape can be heat-sealed to a surface of the carrier tape by pressing such a sealing iron onto the carrier tape from above the cover tape. As a specific method, a repeated sealing method in which the sealing iron is pressed a plurality of times while the embossed carrier tape is transported, or a continuous sealing method in which the heat sealing is performed while the sealing iron is continuously applied to the cover tape side can be applied.

A sealing temperature may be 100 to 240° C. or 120 to 220° C.

The electronic component package of the present embodiment can have a small peel strength range when the cover tape is peeled off. Thus, in the manufacture of electronic equipment, it is possible to greatly reduce a defective mounting rate of the electronic components.

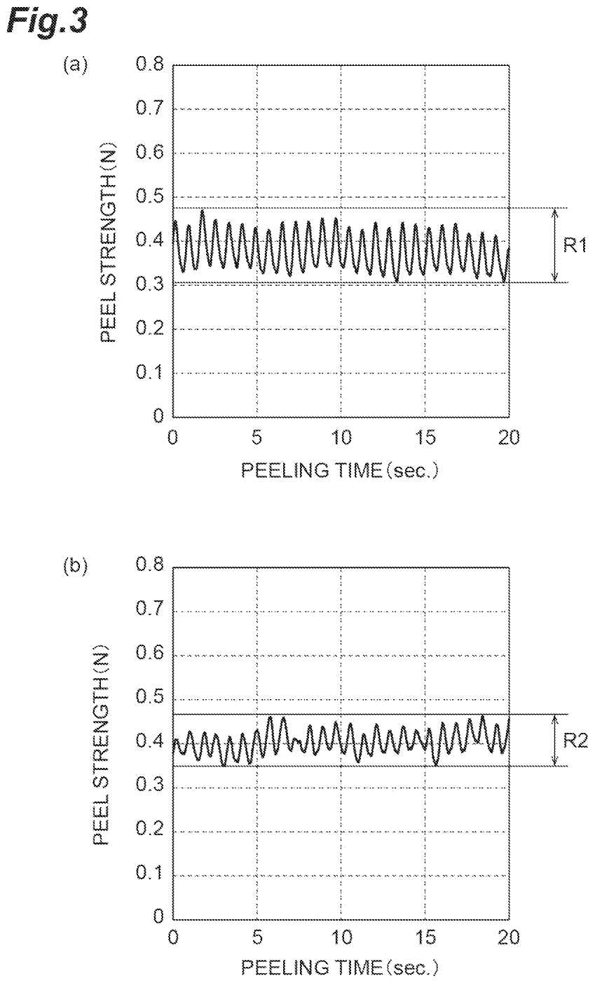

FIG. 3 is a diagram showing an example of a peel strength chart obtained when the cover tape is peeled in a longitudinal direction. FIG. 3(a) shows a peel strength chart when an example of a cover tape with a heat seal layer having a loss tangent tan δ of 1 or more in a temperature range of 150° C. or less in the dynamic viscoelastic measurement at a measurement frequency of 1 Hz is used, and FIG. 3(b) shows a peel strength chart when an example of a cover tape with a heat seal layer having a loss tangent tan δ of less than 1 is used. In the peel strength chart shown in FIG. 3(a), the peel strength of the tape varies greatly in the longitudinal direction, and a peel strength range R₁ exceeds 0.15 N. On the other hand, in the peel strength chart shown in FIG. 3(b), a peel strength range R₂ is less than 0.15 N, and when compared with the cover tape of (a), such a cover tape is less likely to cause problems such as popping out of the electronic components due to vibration during peeling.

### EXAMPLES

Hereinafter, the present invention will be described in more detail with reference to examples and comparative examples, but the present invention is not limited to the following examples.

### Example 1

45 parts by mass of a styrene-butadiene copolymer (manufactured by JSR Corporation, product name “TR2000”, styrene/butadiene mass ratio=40/60), 25 parts by mass of a styrene-butadiene copolymer (manufactured by Denka Co., Ltd., product name “Clearers 170ZR”, styrene/butadiene mass ratio=83/17), and 10 parts by mass of high-impact polystyrene (manufactured by Toyo Styrene Co., Ltd., product name “HIPS H870”) as polystyrene-based resins, and 20 parts by mass of an ethylene-1-butene random copolymer (manufactured by Mitsui Chemicals, Inc., product name “Tafmer A-4085S”) as a polyethylene-based resin were kneaded with a twin-screw extruder to obtain a resin composition constituting a heat seal layer. A two-layer film (having a total thickness of 30 μm) including a first intermediate layer (having a thickness of 20 μm) and a heat seal layer (having a thickness of 10 μm) was obtained by co-extruding the above-described resin composition and a linear low-density polyethylene (manufactured by Ube Maruzen Polyethylene Co., Ltd., product name “Umerit 2040F”) as the first intermediate layer by a T-die method. This two-layer film was laminated with a biaxially stretched polyethylene terephthalate film (manufactured by Toyobo Co., Ltd., product name “Ester film E5100”, thickness of 16 μm) by an extrusion lamination method via a second intermediate layer (having of a thickness of 13 μm) made of a low-density polyethylene resin to obtain a cover tape of Example 1.

### Example 2

A cover tape was obtained in the same manner as in Example 1, except that 20 parts by mass of linear low-density polyethylene (manufactured by Ube Maruzen Polyethylene Co., Ltd., product name “Umerit 0540F”) was used instead of the ethylene-1-butene random copolymer.

### Example 3

A cover tape was obtained in the same manner as in Example 1, except that 15 parts by mass of an ethylene-methyl methacrylate copolymer (manufactured by Sumitomo Chemical Co., Ltd., product name “Acryft WH303-F”, methyl methacrylate content: 18% by mass, ethylene content: 82% by mass) was used as the acrylic-based resin instead of the ethylene-1-butene random copolymer, and the polystyrene resin had the composition shown in Table 1.

(Examples 4 and 5) Cover tapes were obtained in the same manner as in Example 1, except that 10 parts by mass of an ethylene-methyl methacrylate copolymer (manufactured by Sumitomo Chemical Co., Ltd., product name “Acryft WH303-F”, methyl methacrylate content: 18% by mass, ethylene content: 82% by mass) was used as the acrylic-based resin instead of the ethylene-1-butene random copolymer, and the polystyrene resin had the composition shown in Table 1.

### Example 6

A cover tape was obtained in the same manner as in Example 1, except that 10 parts by mass of an ethylene-methyl acrylate copolymer (manufactured by Japan Polyethylene Co., Ltd., product name “Rexpearl EB240H”, methyl acrylate content: 20% by mass, ethylene content: 80% by mass) was used as the acrylic-based resin instead of the ethylene-1-butene random copolymer, and the composition shown in Table 1 was used as the polystyrene resin.

### Example 7

A cover tape was obtained in the same manner as in Example 1, except that 25 parts by mass of an ethylene-methyl methacrylate copolymer (manufactured by Sumitomo Chemical Co., Ltd., product name “Acryft WH303-F”, methyl methacrylate content: 18% by mass, ethylene content: 82% by mass) was used as the acrylic-based resin instead of the ethylene-1-butene random copolymer, and the polystyrene resin had the composition shown in Table 1.

### Comparative Examples 1 and 2

Cover tapes were obtained in the same manner as in Example 1, except that the polystyrene-based resin and the polyethylene-based resin had the compositions shown in Table 1.

The details of raw materials shown in Table 1 and Table 2 are as follows.
SBR: Styrene-butadiene copolymer (manufactured by JSR Corporation, product name “TR2000”, styrene/butadiene mass ratio=40/60)
SBC: Styrene-butadiene copolymer (manufactured by Denka Co., Ltd., product name “Clearen 170ZR”, styrene/butadiene mass ratio=83/17)
HIPS: High impact polystyrene (manufactured by Toyo Styrene Co., Ltd., product name “HIPS H870”)
EB: Ethylene-1-butene random copolymer (manufactured by Mitsui Chemicals, Inc., product name “Tafmer A-4085S”)
LLDPE: Linear low-density polyethylene (manufactured by Ube Maruzen Polyethylene Co., Ltd., product name “Umerit 0540F”)
EMMA: ethylene-methyl methacrylate copolymer (manufactured by Sumitomo Chemical Co., Ltd., product name “Acryft WH303-F”, methyl methacrylate content: 18% by mass, ethylene content: 82% by mass)
EMA: Ethylene-methyl acrylate copolymer (manufactured by Japan Polyethylene Co., Ltd., product name “Rexpearl EB240H”, methyl acrylate content: 20% by mass, ethylene content: 80% by mass)

[Dynamic Viscoelastic Measurement of Heat Seal Layer]

The resin compositions constituting the heat-sealable layers in Examples and Comparative Examples were molded into sheets having a thickness of about 1 to 2 mm to prepare measurement samples. The measurement samples were subjected to a dynamic viscoelastic measurement at 25 to 200° C. under conditions of a shear mode, a heating rate of 5° C./min, a frequency of 1 Hz, a distortion of 0.05%, and a parallel plate having a diameter of 8 mm using a rheometer (manufactured by TA Instruments Co., Ltd., product name “DHR-2”).

The maximum value of the loss tangent tan δ in the temperature range of 150° C. or less was determined based on a measured storage elastic modulus G′ and a loss elastic modulus G″. The results thereof are shown in a table. The table also shows the storage modulus G′(30) at 30° C., the storage modulus G′(150) at 150° C., and G′(30)/G′(150).

The cover tapes of each of the examples and each of the comparative examples were evaluated by the following methods. Results thereof are shown in Tables 1 and 2.

[Evaluation of Peel Strength Range]

A cover tape having a width of 21.5 mm was heat-sealed to a polystyrene carrier tape having a width of 24 mm (manufactured by Denka Co., Ltd., product name: “EC-R”) to obtain a taping sample under conditions of a seal head width of 0.5 mm×2, a seal head length of 24 mm, a seal pressure of 0.5 kgf, a transport length of 12 mm, and a seal time of 0.3 seconds using a taping machine (manufactured by Nagata Seiki Co., Ltd., product name “NK-600”). A heat sealing temperature of each of the cover tapes was adjusted and determined so that an average value of the peel strength obtained from the peel strength chart was 0.4 N (±0.03 N). In each of Examples and Comparative examples, a temperature of the sealing iron was within a range of 100 to 200° C.

The cover tape of the resulting taping sample was peeled off in the longitudinal direction at a peeling angle of 170° to 180° and a peeling speed of 300 mm/min in an atmosphere of 23° C. and a relative humidity of 50%. A difference between the maximum value and the minimum value of peel strength was calculated from the peel strength chart obtained when the cover tape is peeled off 100 mm at this time, and the peel strength range was evaluated with the following criteria.

### <Determination Criteria>

A: The difference between the maximum value and the minimum value of the peel strength is less than 0.15 N
B: The difference between the maximum value and the minimum value of the peel strength is 0.15 N mN or more

TABLE 1

| | | Example 1 | Example 2 | Example 3 | Example 4 | Example 5 | Example 6 | Example 7 |
|---|---|---|---|---|---|---|---|---|
| Polystyrene-based | SBR | 45 | 45 | 45 | 50 | 45 | 45 | 22.5 |
| resin | SBC | 25 | 25 | 35 | 35 | 35 | 35 | 42.5 |
| | HIPS | 10 | 10 | 5 | 5 | 10 | 10 | 10 |
| Polyethylene-based | EB | 20 | — | — | — | — | — | — |
| resin | LLDPE | — | 20 | — | — | — | — | — |
| Acrylic-based resin | EMMA | — | — | 15 | 10 | 10 | — | 25 |
| | EMA | — | — | — | — | — | 10 | — |
| Total (parts by mass) | | 100 | 100 | 100 | 100 | 100 | 100 | 100 |
| Maximum value of loss tangent tanδ in | | 0.8919 | 0.9701 | 0.8247 | 0.8379 | 0.8158 | 0.8149 | 0.9544 |
| the temperature region below 150° C. | | | | | | | | |
| Storage modulus (Pa) | G′(30) @30° C. | 4.71 × 10⁷ | 7.69 × 10⁷ | 4.81 × 10⁷ | 4.93 × 10⁷ | 5.32 × 10⁷ | 5.84 × 10⁷ | 1.03 × 10⁸ |
| | G′(150) @150° C. | 8.27 × 10⁴ | 1.14 × 10⁵ | 1.07 × 10⁵ | 1.05 × 10⁵ | 1.21 × 10⁵ | 1.20 × 10⁵ | 1.05 × 10⁵ |
| G′(30)/G′(150) | | 570 | 675 | 448 | 469 | 441 | 487 | 981 |
| Peel strength range | Range (N) | 0.12 | 0.13 | 0.11 | 0.11 | 0.12 | 0.12 | 0.14 |
| | Determination | A | A | A | A | A | A | A |

TABLE 2

| | | Comparative | Comparative |
|---|---|---|---|
| | | example 1 | example 2 |
| Polystyrene-based | SBR | 12 | 22.5 |
| resin | SBC | 34 | 42.5 |
| | HIPS | 20 | 10 |
| Polyethylene-based | EB | 34 | 25 |
| resin | LLDPE | — | — |
| Acrylic-based resin | EMMA | — | — |
| | EMA | — | — |
| Total (parts by mass) | | 100 | 100 |
| Maximum value of loss tangent tanδ in | | 1.165 | 1.179 |
| the temperature region below 150° C. | | | |
| Storage modulus (Pa) | G'(30) @30° C. | 1.67 × 10⁸ | 1.72 × 10⁸ |
| | G'(150) @150° C. | 1.16 × 10⁵ | 1.27 × 10⁵ |
| G'(30)/ G'(150) | | 1443 | 1359 |
| Peel strength range | Range (N) | 0.17 | 0.17 |
| | Determination | B | B |

As shown in Table 1, it was confirmed that the cover tapes of Examples 1 to 7 provided with a heat seal layer having a loss tangent tan δ of less than 1 in a temperature range of 150° C. or lower can curb the peel strength range to 0.15N or less even when being heat-sealed so that an average value of the peel strength is 0.4N.

### REFERENCE SIGNS LIST

1 Base layer
2 Heat seal layer
3, 3a, 3b Intermediate layer
16 Embossed carrier tape
20 Accommodating portion
30 Transport hole
40 Electronic component
50, 52 Cover tape
200 Electronic component package

1. A cover tape comprising:
at least a base layer, and a heat seal layer,
wherein the heat seal layer has a loss tangent tan δ of less than 1 in a temperature range of 150° C. or less in a dynamic viscoelastic measurement at a measurement frequency of 1 Hz.

2. The cover tape according to claim 1, wherein the heat seal layer contains one or more resins selected from a group consisting of a polystyrene-based resin, a polyethylene-based resin, and an acrylic-based resin.

3. The cover tape according to claim 1, wherein the heat seal layer has a ratio [G′(30)/G′(150)] of storage elastic modulus G′(30) at 30° C. to storage elastic modulus G′(150) at 150° C. of 800 or less in the dynamic viscoelastic measurement at a measurement frequency of 1 Hz.

4. The cover tape according to claim 1, wherein the heat seal layer has a storage elastic modulus G′(30) at 30° C. of 1.0×10⁶ Pa or more and less than 1.0×10⁸ Pa in the dynamic viscoelastic measurement at the measurement frequency of 1 Hz.

5. An electronic component package comprising:
a carrier tape having an accommodating portion;
electronic components accommodated in the accommodating portion of the carrier tape; and
the cover tape according to claim 1 heat-sealed to the carrier tape as a cover material.
